(19) United States
(12) Patent Application Publication
(10) Pub. No.: US 2009/0224344 A1
(43) Pub. Date: Sep. 10, 2009

(54) Packaging method of image sensing device

(75) Inventors: Chi-Chih Huang, Tao-Yuan Hsien (TW); Chih-Yang Hsu, Tao-Yuan Hsien (TW)

Correspondence Address: BACON & THOMAS, PLLC, 625 SLATERS LANE, FOURTH FLOOR, ALEXANDRIA, VA, 22314-1176, US

(73) Assignee: Impac Technology Co., Ltd., Tao-Yuan Hsien (TW)

(21) Appl. No.: 12/073,594

(22) Filed: Mar. 7, 2008

(51) Int. Cl. H01L 31/0203; H01L 31/18

(52) U.S. Cl. 257/432; 438/64; 257/E31.11

(57) ABSTRACT

A packaging method for an image sensing device is disclosed. The packaging method includes the steps of a) providing a wafer having at least an image sensing module with a light-receiving region exposed; b) forming a barrier around the light-receiving region on the image sensing module; c) dicing the wafer for forming an individual device with the image sensing module; and d) forming a transparent lid supported by the barrier above the light-receiving region of the image sensing module.

### FIELD OF THE INVENTION

The present invention relates to a semiconductor packaging method, and more particularly, to a packaging method of an image sensing device.

### BACKGROUND OF THE INVENTION

In recent years, solid-state image sensors such as charge coupled devices (CCDs) or complementary metal oxide semiconductor (CMOS) image sensors have been widely applied to electronic products for converting light into electrical signals. The applications of image sensor components include monitors, cell phones, transcription machines, scanners, digital cameras, and so on.

Integrated circuits (ICs) are manufactured as wafers, each wafer containing many individual circuits (die). After fabrication, a wafer is cut (“singulated”) into individual die. Each die is then encapsulated in a plastic or ceramic package or is attached to a ceramic cap.

Each die includes several electrical contact pads. During packaging, each of these contact pads is connected to a respective lead or another external structure. In one common practice, a bonding wire is welded between each contact pad and a respective lead. The leads or other structures are used to electrically connect a completed IC to a circuit board or the like, such as by soldering. These solder connections often also provide the sole mechanical connection between the IC and the circuit board.

For example, U.S. Pat. No. 6,268,231 discloses a CCD package 10 as shown in FIG. 1. The CCD package 10 includes a plastic base structure 12 for support beneath a flexible circuit board 18. Electrical conductors are formed upon flexible circuit board 18. Plastic ring frame 14 is placed on top of the flexible circuit board 18 creating a sandwich area defined by the base structure 12 and plastic ring frame 14 with flexible circuit 18 in between. The plastic ring frame 14 provides depth for an image sensor to be contained therein. The image sensor electrical connectors that make electrical contact with conductor pattern on the flexible circuit 18. The ring frame 14 provides support for a cover glass 16 that provides isolation from ambient conditions for the enclosed CCD while allowing light to pass and become incident upon the CCD.

However, packaging an individual die can be time consuming and expensive, because each die must be packaged individually. Given the reliance of the electronics industry on ICs, reducing the cost of each IC can lead to a substantial overall cost saving. Therefore, a packaging method that can reduce the production time and cost is desired.

### SUMMARY OF THE INVENTION

Accordingly, the prior arts are limited by the above problems. It is an object of the present invention to provide a packaging method that can reduce the production time and cost of an image sensing device.

In accordance with an aspect of the present invention, a packaging method for an image sensing device, includes the steps of a) providing a wafer having at least an image sensing module with a light-receiving region exposed; b) forming a barrier around the light-receiving region on the image sensing module; c) dicing the wafer for forming an individual device with the image sensing module; and d) forming a transparent lid supported by the barrier above the light-receiving region of the image sensing module.

Preferably, the packaging method further includes the steps of e) providing an annular dam on a substrate; f) mounting the image sensing module inside the annular dam on the substrate; g) connecting the image sensing module and the substrate via a plurality of bonding wires; h) filling an adhesive between the barrier and the annular dam with the plurality of bonding wires being encapsulated.

Preferably, the packaging method further includes a step of cutting off the annular dam.

Preferably, the image sensing module includes complementary metal oxide semiconductor (CMOS) image sensor or charge coupled device (CCD) image sensor.

Preferably, the substrate includes aluminum nitride ceramic, fiberglass-reinforced epoxy resin, or bismaleimide-triazine resin.

Preferably, the barrier is formed by transfer molding, pot molding, injection molding, photolithographic process, exposure development process, laser cutting process, or stereolithographic process.

Preferably, the barrier is defined using a photoresist mask.

Preferably, the barrier is made of epoxy, solder mask, or photoresist.

In accordance with another aspect of the present invention, an image sensing device includes a substrate; an image sensing module mounted on the substrate, having a light-receiving region exposed; a plurality of bonding wires for connecting the image sensing module and the substrate; a barrier formed around the light-receiving region on the image sensing module; an adhesive filled around the barrier with the plurality of bonding wires being encapsulated; and a transparent lid formed above the light-receiving region.

### BRIEF DESCRIPTION OF THE DRAWING

The above objects and advantages of the present invention will become more readily apparent to those ordinarily skilled in the art after reviewing the following detailed description and accompanying drawings, in which:

FIG. 1 illustrates an image sensing device according to the prior art.

FIGS. 2A-2I illustrate an embodiment of a packaging method for an image sensing device according to the present invention.

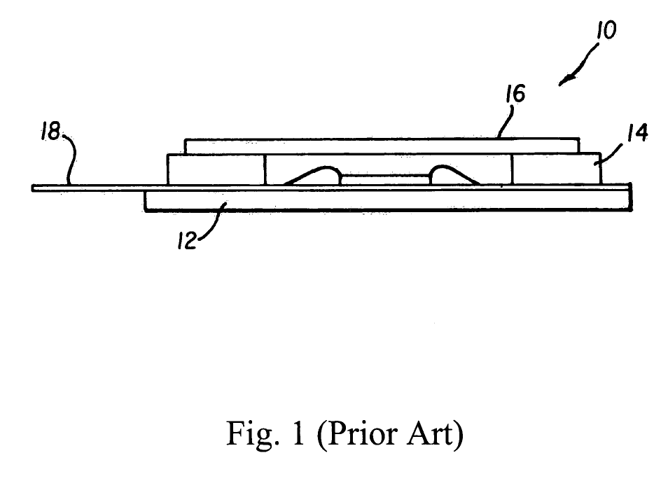

### DETAILED DESCRIPTION OF THE PREFERRED EMBODIMENT

The present invention will now be described more specifically with reference to the following embodiment. It is to be noted that the following descriptions of the preferred embodiment of this invention are presented herein for purpose of illustration and description only; it is not intended to be exhaustive or to be limited to the precise form disclosed.

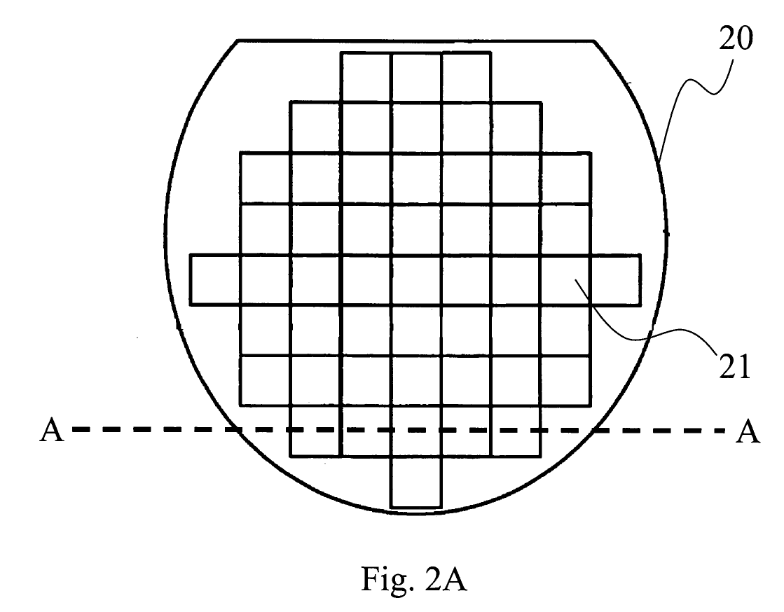

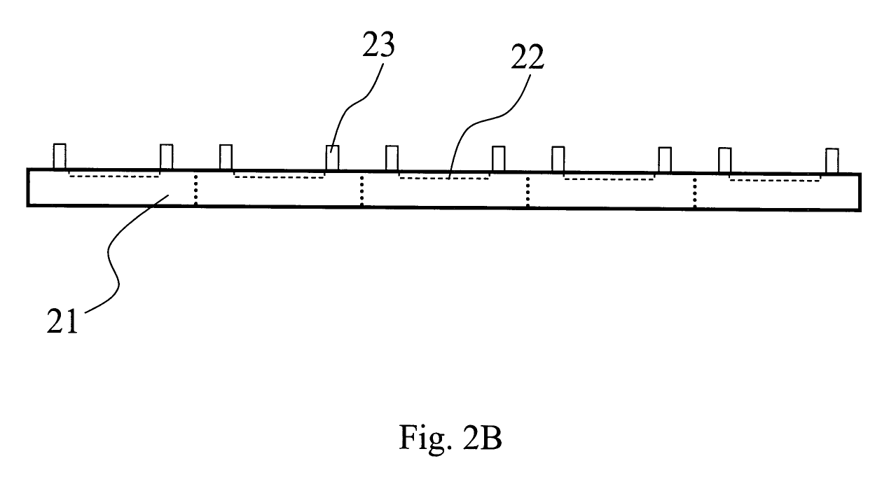

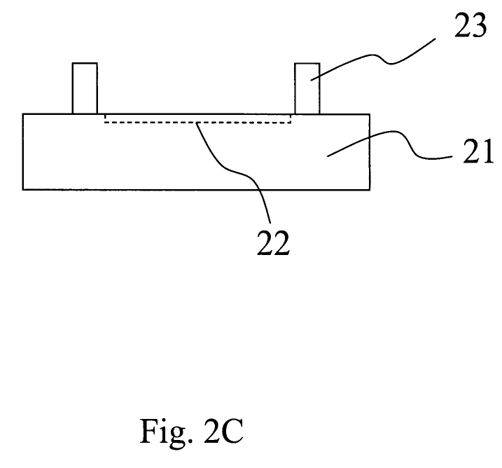

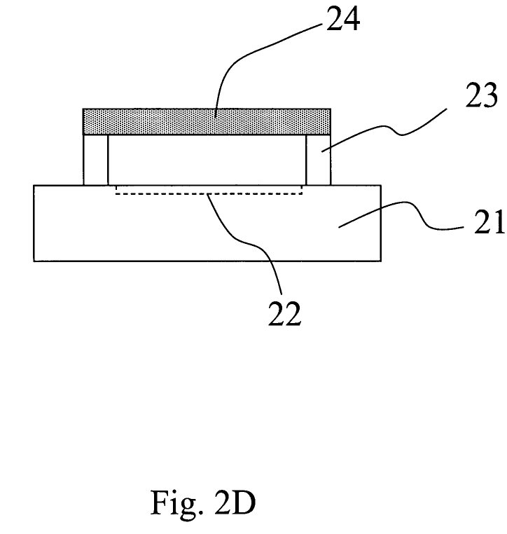

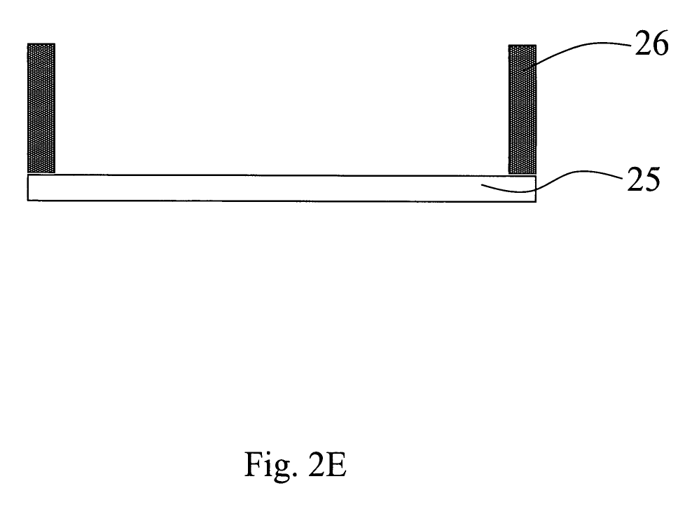

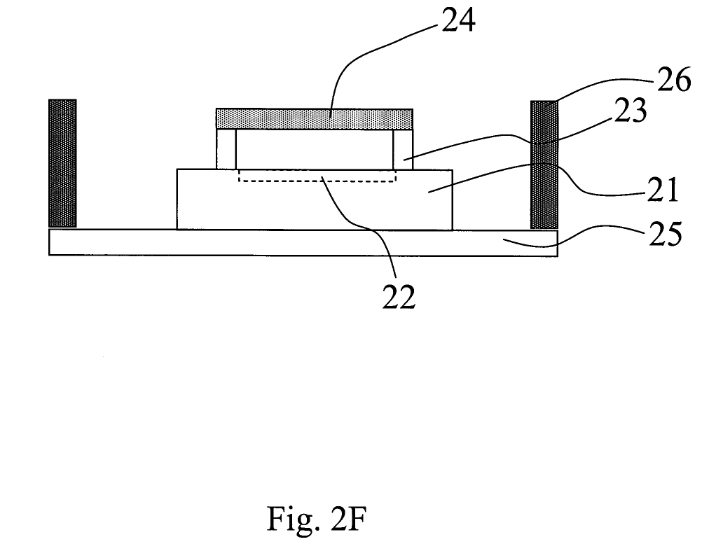

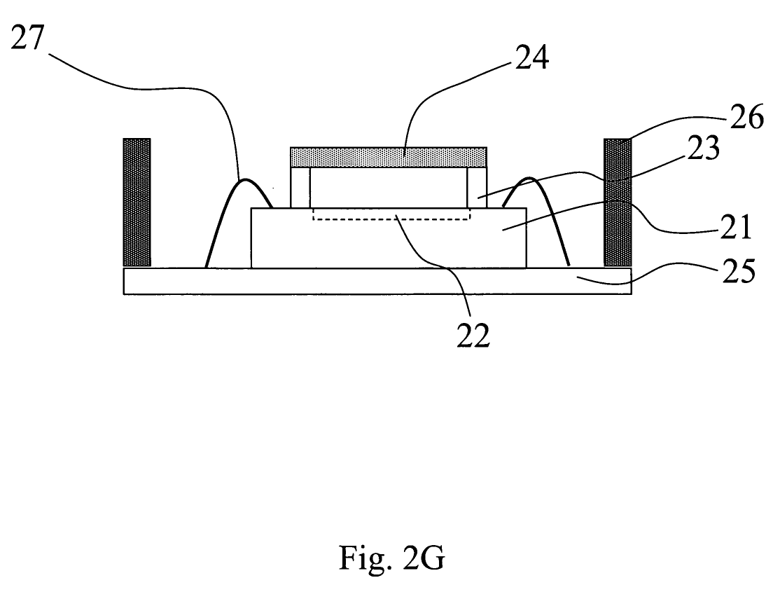

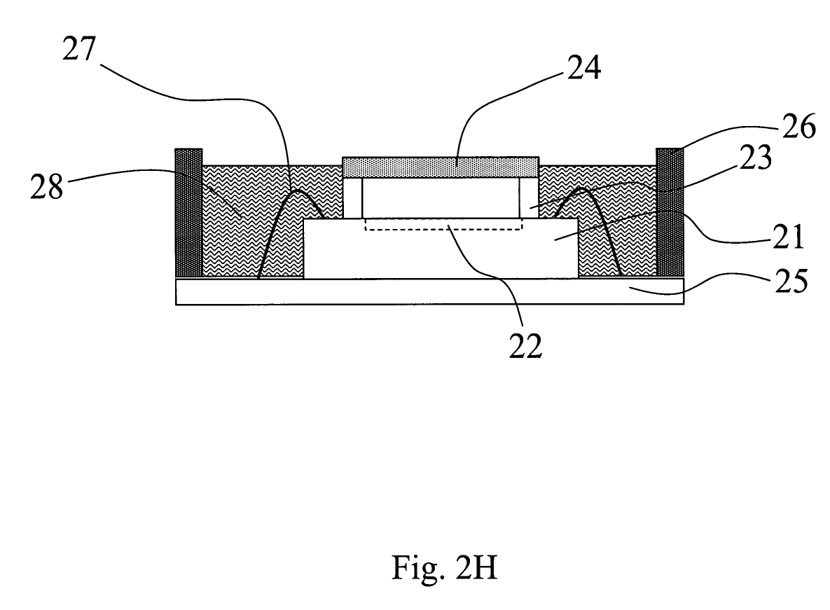

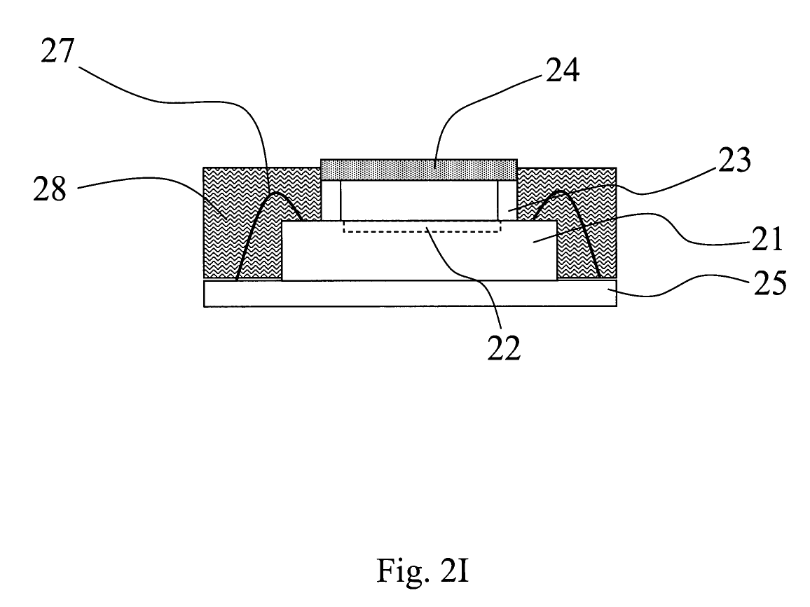

Please refer to FIGS. 2A-2I. They illustrate an embodiment of a packaging method for an image sensing device according to the present invention. FIG. 2A is a top view diagram of an integrated circuit (IC) wafer 20. The wafer 20 contains at least one image sensing module 21 which is also known as “die”. Usually, a wafer has hundreds or thousands of image sensing modules depending on the size of each image sensing module. The smaller size of each image sensing module is, the more modules the wafer can accommodate. FIG. 2B is a cross-sectional diagram cut along line A-A in FIG. 2A showing five image sensing modules 21.

The image sensing modules 21 each has a light-receiving region 22 exposed and a barrier 23 formed around the light-receiving region 22, as shown in FIG. 2B. The barrier 23 can be made of epoxy, solder mask, or photoresist, and can be formed by transfer molding, pot molding, injection molding, photolithographic process, exposure development process, laser cutting process, or stereolithographic process.

Traditionally, a barrier is formed on an image sensing module after the image sensing module is singulated from the wafer. However, since the barrier 23 has a certain volume and height, the barrier 23 of each image sensing modules 21 can be formed concurrently, for example, by applying a photoresist mask on the wafer 20 before the wafer is diced. By this way, the production time and cost may be reduced.

After the barrier 23 is formed on each of the image sensing modules 21, the wafer 20 is diced to form an individual device with the image sensing module 21, as shown in FIG. 2C. Later, a transparent lid 24 is disposed on the barrier 23 above the light-receiving region 22 of the image sensing module 21, as shown in FIG. 2D. Conventionally, a transparent lid is not added until the packaging process is to be finalized and a protection layer is introduced to protect a light-receiving region from being damaged or polluted during packaging process. In contrast, the transparent lid 24 of the present invention acts as a protection layer to protect the light-receiving region 22, and therefore, the cost and time are saved for producing and removing such protection layer.

Once the transparent lid 24 is added, the packaged image sensing module 21 is mounted on a substrate 25 inside an annular dam 26 provided on the substrate 25, as shown in FIGS. 2E and 2F. Then, the image sensing module 21 is connected to the substrate 25 via bonding wires 27, as shown in FIG. 2G. The annular dam 26 can be made of plastic, fiberglass-reinforced epoxy resin, or bismaleimide-triazine resin. Meanwhile, the substrate 25 can be made of aluminum nitride ceramic, fiberglass-reinforced epoxy resin, or bismaleimide-triazine resin for improving the thermal conductivity.

Furthermore, the image sensing module 21 is mounted on the substrate 25 in a conventional manner such as tape lamination process. Usually, there are a lot of connecting pads (not shown) disposed on the image sensing module 21 and the substrate 25. Accordingly, those connecting pads of the image sensing module 21 and the substrate 25 are conducted via the bonding wires 27.

Next, an adhesive 28 is filled between the barrier 23 and the annular dam 26 with the bonding wires 27 being encapsulated, as shown in FIG. 2H. The adhesive 28 is used to prevent the bonding wires 27 from being damaged.

Finally, the annular dam 26 and a part of the substrate 25 are cut off to reduce the size of the image sensing device, as shown in FIG. 2I.

In practice, the image sensing module 21 of the present invention could be complementary metal oxide semiconductor (CMOS) image sensor or charge coupled device (CCD) image sensor.

In conclusion, the present invention discloses a packaging method that forms a barrier on an image sensing module concurrently on wafer-level and uses a transparent lid as a protection layer which in turn reduces the overall production time and cost.

While the invention has been described in terms of what is presently considered to be the most practical and preferred embodiment, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A packaging method for an image sensing device, comprising the steps of:
a) providing a wafer having at least an image sensing module with a light-receiving region exposed;
b) forming a barrier around said light-receiving region on said image sensing module;
c) dicing said wafer for forming an individual device with said image sensing module; and
d) forming a transparent lid supported by said barrier above said light-receiving region of said image sensing module.

2. The packaging method according to claim 1, further comprising the steps of:
e) providing an annular dam on a substrate;
f) mounting said image sensing module inside said annular dam on said substrate;
g) connecting said image sensing module and said substrate via a plurality of bonding wires;
h) filling an adhesive between said barrier and said annular dam with said plurality of bonding wires being encapsulated.

3. The packaging method according to claim 2, further comprising a step of cutting off said annular dam.

4. The packaging method according to claim 1, wherein said image sensing module comprises complementary metal oxide semiconductor (CMOS) image sensor or charge coupled device (CCD) image sensor.

5. The packaging method according to claim 2, wherein said substrate comprises aluminum nitride ceramic, fiberglass-reinforced epoxy resin, or bismaleimide-triazine resin.

6. The packaging method according to claim 1, wherein said barrier is formed by transfer molding, pot molding, injection molding, photolithographic process, exposure development process, laser cutting process, or stereolithographic process.

7. The packaging method according to claim 1, wherein said barrier is defined using a photoresist mask.

8. The packaging method according to claim 1, wherein said barrier is made of epoxy, solder mask, or photoresist.

9. An image sensing device, comprising:
a substrate;
an image sensing module mounted on said substrate, having a light-receiving region exposed;
a plurality of bonding wires for connecting said image sensing module and said substrate;
a barrier formed around said light-receiving region on said image sensing module;
an adhesive filled around said barrier with said plurality of bonding wires being encapsulated; and
a transparent lid formed above said light-receiving region.

10. The image sensing device according to claim 9, wherein said image sensing module comprises complementary metal oxide semiconductor (CMOS) image sensor or charge coupled device (CCD) image sensor.

11. The image sensing device according to claim 9, wherein said substrate comprises aluminum nitride ceramic, fiberglass-reinforced epoxy resin, or bismaleimide-triazine resin.

12. The image sensing device according to claim 9, wherein said barrier is formed by transfer molding, pot molding, injection molding, photolithographic process, exposure development process, laser cutting process, or stereolithographic process.

13. The image sensing device according to claim 9, wherein said barrier is defined using a photoresist mask.

14. The image sensing device according to claim 9, wherein said barrier is made of epoxy, solder mask, or photoresist.
